(19) United States
(12) Patent Application Publication
(10) Pub. No.: US 2011/0092049 A1
(43) Pub. Date: Apr. 21, 2011

(54) METHOD AND APPARATUS FOR SUBSTRATE BONDING

(76) Inventors: Zhenfang Chen, Sunnyvale, CA (US); Jeffrey Birkmeyer, San Jose, CA (US); Andreas Bibl, Los Altos, CA (US); John A. Higginson, Santa Clara, CA (US)

(21) Appl. No.: 12/991,808

(22) PCT Filed: May 8, 2009
(86) PCT No.: PCT/US09/43336

§ 371 Date: Jan. 4, 2011

Related U.S. Application Data
(60) Provisional application No. 61/055,708, filed on May 23, 2008.

(51) Int. Cl. H01L 21/30

(52) U.S. Cl. 438/455; 257/E21.211

(57) ABSTRACT

Methods for bonding a first substrate to a second substrate are described. A surface of the first substrate is coated with an adhesive layer. The adhesive layer is cured to b-stage. The surface of the first substrate is positioned in contact with the second substrate. An edge of the first substrate is pressed to an edge of the second substrate to initiate Van der Waals bonding. The first and second substrates are allowed to come together by Van der Waals bonding. The bonded first and second substrates are subjected to a sufficient heat for a sufficient time period to cure completely the adhesive layer.

### TECHNICAL FIELD

The following description relates to bonding substrates.

### BACKGROUND

A fluid ejection system, for example, an ink jet printer, typically includes an ink path from an ink supply to an ink nozzle assembly that includes nozzles from which ink drops are ejected. Ink is just one example of a fluid that can be ejected from a jet printer. Ink drop ejection can be controlled by pressurizing ink in the ink path with an actuator, for example, a piezoelectric deflector, a thermal bubble jet generator, or an electrostatically deflected element. A typical printhead module has a line or an array of nozzles with a corresponding array of ink paths and associated actuators, and drop ejection from each nozzle can be independently controlled. In a so-called “drop-on-demand” printhead module, each actuator is fired to selectively eject a drop at a specific location on a medium. The printhead module and the medium can be moving relative one another during a printing operation.

In one example, a printhead module can include a semiconductor printhead body and a piezoelectric actuator. The printhead body can be made of silicon etched to define pumping chambers. Nozzles can be defined by a separate substrate (i.e., a nozzle layer) that is attached to the printhead body. The piezoelectric actuator can have a layer of piezoelectric material that changes geometry, or flexes, in response to an applied voltage. Flexing of the piezoelectric layer causes a membrane to flex, where the membrane forms a wall of the pumping chamber. Flexing the membrane thereby pressurizes ink in a pumping chamber located along the ink path. The piezoelectric actuator is bonded to the membrane.

### SUMMARY

This invention relates to bonding substrates. In general, in one aspect, the invention features a method for bonding a first substrate to a second substrate. A surface of the first substrate is coated with an adhesive layer. The adhesive layer is cured to b-stage. The surface of the first substrate is positioned in contact with the second substrate. An edge of the first substrate is pressed to an edge of the second substrate to initiate Van der Waals bonding. The first and second substrates are allowed to come together by Van der Waals bonding. The bonded first and second substrates are subjected to a sufficient heat for a sufficient time period to cure completely the adhesive layer.

Implementations of the invention can include one or more of the following features. The first substrate can be an actuator layer including a piezoelectric layer and the second substrate can be a silicon membrane. The method can further include, prior to coating the surface of the first substrate with the adhesive layer, oxygen plasma treating the surface. Prior to positioning the first substrate and the second substrate in contact, the second substrate can be subjected to RCA-1 cleaning.

The adhesive layer can be benzocyclobutene spun-on to the surface of the first substrate. Pressing an edge of the first substrate to an edge of the second substrate can include applying a force in the range of approximately 5 to 20 psi. Prior to coating the surface of the first substrate with an adhesive layer, the surface can be subjected to a chemical-mechanical polishing. The adhesive layer can be benzocyclobutene and the bonded first and second substrates can be heated to approximately 200° Celsius for approximately 40 hours to completely cure the benzocyclobutene. The adhesive layer can have a total thickness variation of approximately 1.5% or less.

Implementations of the invention can realize one or more of the following advantages. Initially bonding two substrates together with Van der Waals bonds and then heating the bonded substrates to complete curing of an adhesive layer therebetween avoids applying significant pressure to the substrates, for example, using a chuck. Conventional bonding techniques that require applying pressure can be sensitive to the slightest deviations from an entirely flat surface. For example, a slight raised area on the chuck can affect the thickness of the adhesive layer in the vicinity of the substrate in contact with the raised area of the chuck. Varying thickness of the adhesive layer can have significant adverse effects. For example, bonding a piezoelectric actuator to a membrane positioned in contact with a pumping chamber requires a uniform bonding layer. A thickness variation in the bonding layer can adversely affect the jetting characteristics of the pumping chamber, e.g., causing some jets to fire more quickly than others. The bonding techniques described herein avoid applying pressure to effect the bond, and are therefore less sensitive to non-flatness in the bonding surfaces or surfaces on which the substrates are in contact during bonding. Including an adhesive layer between the substrates, which is initially at b-stage and later completely cured, creates a relatively strong bond between the substrates, as compared to the initial Van der Waals bond.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a cross-sectional view of portion of an example printhead module including an actuator bonded to a membrane.

FIG. 2A is a plan view of a portion of an example printhead module showing rows of actuators positioned over rows of pumping chambers.

FIG. 2B is an enlarged cross-sectional view of a portion of the printhead module of FIG. 1.

FIG. 3 is a flowchart showing an example process for bonding an actuator layer to a membrane.

FIGS. 4A-C show cross-sectional views of the actuator layer being bonded to the membrane.

Like reference symbols in the various drawings indicate like elements.

### DETAILED DESCRIPTION

It can be important to have a uniform bonding layer when bonding two flat substrates together. A method, apparatus, and system are described for bonding a first substrate to a second substrate with an adhesive layer therebetween. An initial bond is formed using Van der Waals bonding with the adhesive in a partially cured state, followed by a complete curing of the adhesive.

In one illustrative example, the first substrate is an actuator (or at least a portion thereof, as is discussed further below) and the second substrate is a membrane for use in a printhead module including a pumping chamber. Actuating the actuator flexes the membrane and thereby pressurizes the pumping chamber to eject a droplet of printing fluid. A conventional technique of bonding a piezoelectric actuator to a silicon membrane can include applying an adhesive to one or both substrates, applying a force (e.g., 5000 N) to press the two substrates together for a period of time (e.g., 3-4 hours) and then heating the two substrates to the curing temperature of the adhesive layer to complete the bond. However, many factors can adversely affect the uniformity of the adhesive layer, such as the flatness of the surfaces being bonded, the flatness of the surfaces applying a force and the uniformity of the force being applied. When bonding a piezoelectric actuator to a membrane positioned over a pumping chamber, a thickness variation in the adhesive layer can adversely affect the jetting characteristics of the pumping chamber. For example, some jets may fire faster than neighboring jets.

A more uniform adhesive layer can be achieved by initially bonding two surfaces together using Van der Waals forces, where at least one surface is coated in an adhesive. The adhesive can then be cured to further strengthen the bond between the two surfaces. For illustrative purposes, the bonding technique is described in the context of bonding an actuator (or portion thereof) to a membrane and can be used in printhead modules of varying configurations. However, it should be understood that the bonding techniques described can be used to bond other types of substrates for the same or different applications. An exemplary fluid deposited by the printhead module is ink. However, it should be understood that other fluids can be used, for example, electroluminescent material used in the manufacture of light emitting displays, liquid metals used in circuit board fabrication, or biological fluid.

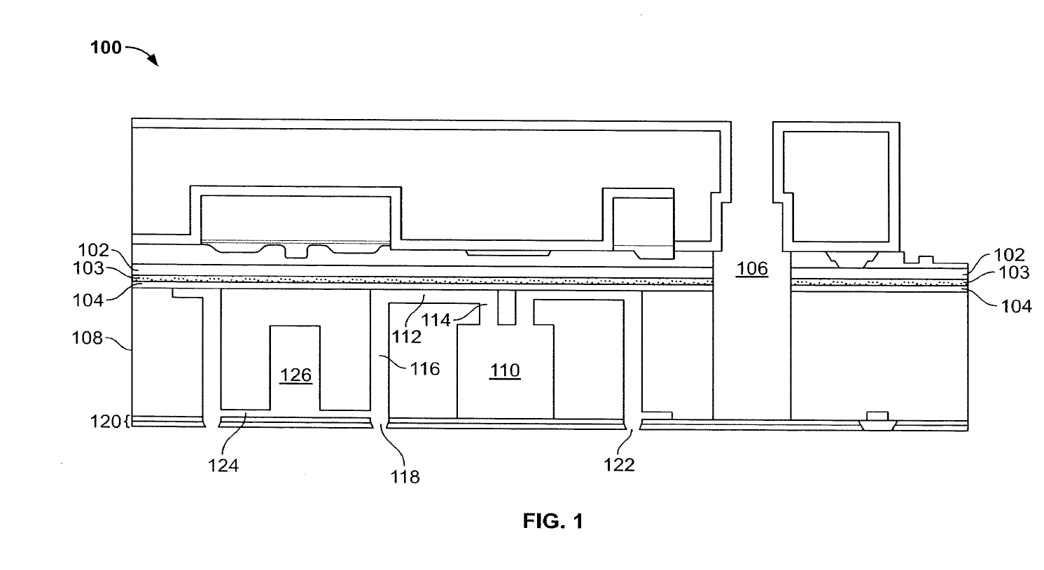

Referring to FIG. 1, for illustrative purposes only, and without being limited to the particular printhead module 100 shown, the techniques shall be described in the context of bonding an actuator 102 to a membrane 104. A cross-sectional view of a portion of printhead module 100 is shown. The printhead module 100 includes a substrate 108 in which a plurality of fluid flow paths are formed (only one flow is shown). The printhead module 100 also includes a plurality of actuators to cause fluid to be selectively ejected from the flow paths. Thus, each flow path with its associated actuator provides an individually controllable MEMS fluid ejector.

In this implementation of printhead module, an inlet 106 fluidly connects a fluid supply (not shown) to a substrate 108. The inlet 106 is fluidly connected to an inlet passage 110 through a channel (not shown). The inlet passage 110 is fluidly connected to a pumping chamber 112, for example, through an ascender 114. The pumping chamber 112 is fluidly connected to a descender 116 terminating in a nozzle 118. The nozzle 118 can be defined by a nozzle layer 120 attached to the substrate 108. The nozzle 118 includes an outlet 122 defined by an outer surface of the nozzle layer 120. In some implementations, a recirculation passage 124 can be provided to fluidly connect the descender 116 to a recirculation channel 126.

The membrane 104 is formed on top of the substrate 108 in close proximity to the pumping chamber 112, e.g. a lower surface of the membrane 104 can define an upper boundary of the pumping chamber 112. The actuator 102 is disposed on top of the membrane 104, and an adhesive 103 is between the actuator 102 and the membrane 104.

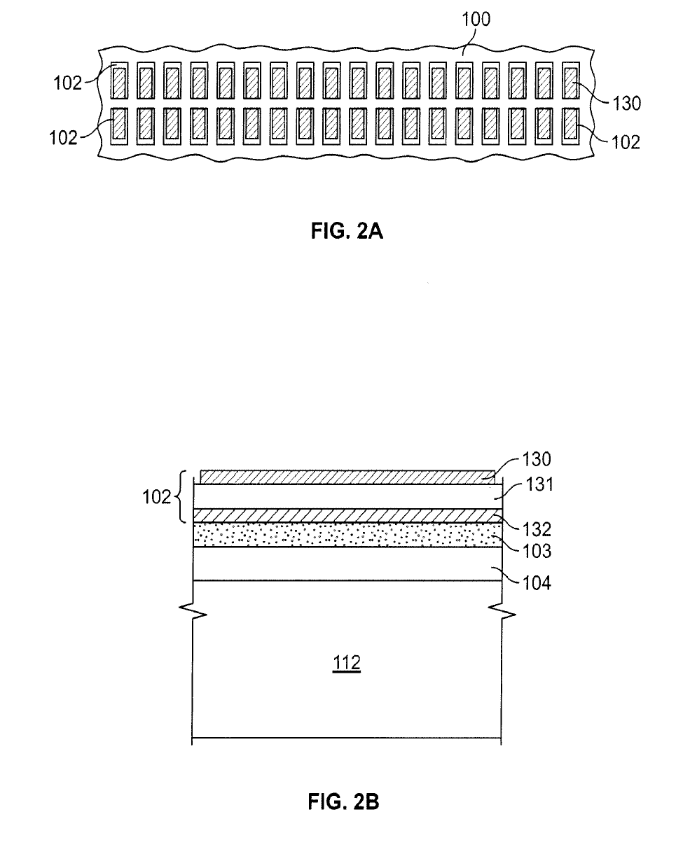

Referring to FIG. 2A, a plan view is shown of a portion of the printhead module 100. In some implementations, each pumping chamber 112 has a corresponding electrically isolated actuator 102 that can be actuated independently. In this implementation, two rows of actuators 102 are shown. The two rows of actuators 102 correspond to two rows of pumping chambers 112, which can correspond to two rows of nozzles 118 beneath the pumping chamber 112.

Referring to FIG. 2B, in this implementation, the actuator 102 includes a piezoelectric layer 131 between electrodes 130 and 132, to allow for actuation of the actuator 102 by a circuit (not shown). For example, electrode 130 can be a drive electrode and electrode 132 can be a ground electrode, where a voltage applied to the drive electrode 130 creates a voltage differential across the piezoelectric layer 131, causing the piezoelectric material to deform. This deformation can deflect the membrane 104 into the pumping chamber 112, thereby forcing fluid out of the pumping chamber 112.

Because the piezoelectric layer 131 is typically formed as a very thin layer, e.g., less than 20 microns that can be difficult to handle without damaging the layer, the actuator 102 can be formed in at least the following two ways, although other forming techniques are possible. In one technique, the bottom electrode, i.e., electrode 132, is formed on the bottom of a relatively thick piezoelectric layer. In this implementation, the thick piezoelectric layer with the electrode 132 formed thereon is referred to herein as the “actuator layer”, since it is not actually the actuator, but includes some components thereof at a stage in the actuator forming process. The actuator layer can then be bonded to the membrane 104, which is already bonded to substrate 108, using the bonding methods described herein. The thick piezoelectric layer can then be planarized to reduce the thickness to the desired thickness, i.e., to form the piezoelectric layer 131. The top electrode, i.e., electrode 130, can then be formed on top of the piezoelectric layer 131.

In another technique, a relatively thick piezoelectric layer is formed on a support wafer. The piezoelectric layer is then planarized to reduce the thickness to the desired thickness, i.e., to form the piezoelectric layer 131. The support wafer provides the rigidity needed to form such a thin layer of the piezoelectric material. The exposed surface of the piezoelectric layer 131 is then metalized to form the bottom electrode, i.e., electrode 132. In this implementation, the piezoelectric layer 131 attached to the support wafer and with the electrode 132 formed thereon is the “actuator layer”. The actuator layer is bonded to the membrane 104 using the bonding methods described herein. The support wafer can then be removed from the piezoelectric layer 131. The newly exposed surface of the piezoelectric layer 131 can then be metalized to form the top electrode, i.e., electrode 130.

The membrane 104 can be formed of silicon (e.g., single crystalline silicon), some other semiconductor material, oxide, glass, aluminum nitride, silicon carbide, other ceramics or metals, silicon-on-insulator, or any depth-profilable substrate. For example, the membrane 104 can be composed of an inert material and have compliance such that actuation of the actuator 102 causes flexure of the membrane 104 sufficient to pressurize fluid in the pumping chamber 112. In some implementations, the membrane 104 can have a thickness of between about 1 micron and about 150 microns. More particularly, in some implementations the thickness ranges between approximately 8 to 20 microns. U.S. Patent Publication No. 2005/0099467, entitled “Print Head with Thin Membrane” filed by Bibl et al on Oct. 8, 2004 and published May 12, 2005, the entire contents of which is hereby incorporated by reference, describes examples of printhead modules and fabrication techniques.

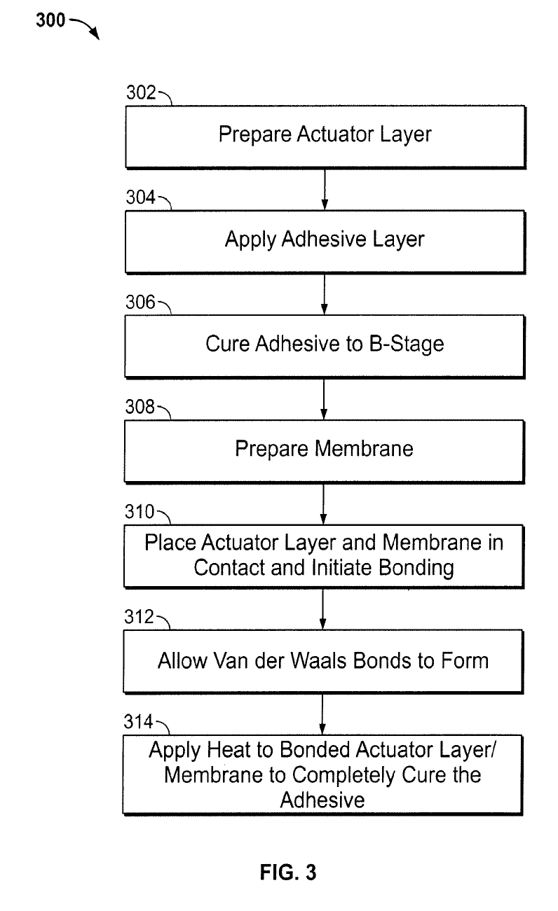

FIG. 3 is a flow chart of an example process 300 for bonding an actuator layer to a membrane. For illustrative purposes, the actuator layer can be components at a stage in a process of forming the actuator 102 shown in FIGS. 1-2B, as was discussed above in reference to FIG. 2B. The membrane can be membrane 104. However, it should be understood the process 300 can be used with other configurations of actuator 102 and membrane 104 used in the same or differently configured printhead modules.

The actuator layer is prepared (step 302) by cleaning at least the surface to be bonded to the membrane 104. In some implementations, an 0₂ plasma cleaning process is used. The surface is treated with 0₂ plasma to chemically activate the surface, which can improve the bonding of the adhesive to the surface.

A layer of adhesive is applied to the surface of the actuator layer to be bonded to the membrane 104 (step 304). The adhesive 26 can be an organic material, such as an epoxy (e.g., polyimide or benzocyclobutene (BCB)), or other suitable material. The adhesive can be applied by spin-on processing to a thickness of, for example, about 0.3 to 3 micron. In a particular example, the adhesive has a thickness of approximately 1.2 microns. The adhesive is a thermosetting adhesive, e.g., an adhesive including a thermosetting resin, and is partially cured to a “b-stage” (step 306). B-stage refers to a secondary stage in the reaction of some thermosetting resins, characterized by softening of the resin when heated and swelling when in the presence of certain liquids, but without complete fusing or dissolving. The b-stage can also characterized by a progressive increase in viscosity.

In an implementation where the adhesive is BCB, the BCB can be heated at approximately 100° Celsius (C) for approximately 20 minutes to achieve b-stage.

The surface of the membrane 104 to be bonded to the actuator layer is prepared (step 308). Particles that may interface with bonding and/or jetting performance are removed from the surface. In one implementation, the membrane 104 is cleaned in an RCA bath of ammonium hydroxide and hydrogen peroxide solution at approximately 70° C. for 10 minutes, i.e., a standard RCA-1 cleaning.

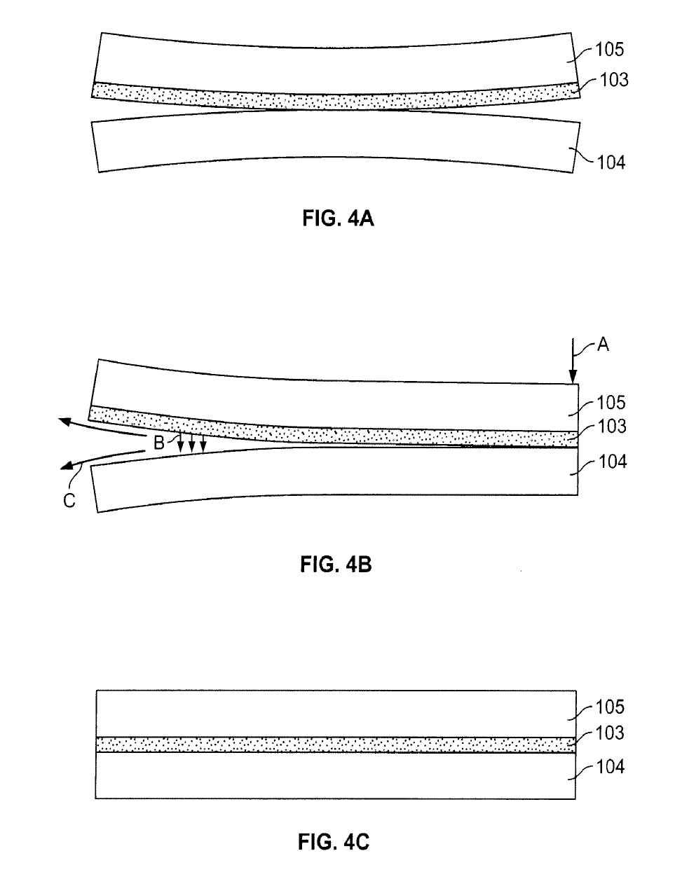

Once both the actuator layer and membrane 104 have been prepared, the actuator layer is placed in contact with the membrane 104 (step 310). For example, as shown in FIG. 4A, the actuator layer is placed on top of the membrane 104. Typically the actuator layer and membrane 104 can each have approximately 30-50 microns of bow, which for illustrative purposes is shown in an exaggerated fashion in FIG. 4A, where the actuator layer is represented by element 105.

Referring to FIG. 4B, the actuator layer 105 and membrane 104 are forced into direct contact along an edge to initiate a Van der Waals bond (step 310). A relatively small force, e.g., an approximate 5 psi force can be used to initiate bonding. The adhesive-coated actuator layer 105 and the membrane 104 gradually come together and are hold together by Van der Waals bonds (see FIG. 4C). As the actuator layer 105 and the membrane 104 come together, air between the two components is forced out, leaving a flat, uniform bonding layer. In some implementations, the actuator layer 105 and the membrane 104 can be bonded together in approximately 10 minutes using this technique. In some implementations, a vacuum thermo-compression bonder, e.g., an EVG bonder available from EV Group of St. Florian/Inn, Austria, can be used to apply the relatively small force to initiate the Van der Waals bond.

The bonded actuator layer 105 and membrane 104 can then be transferred to an oven and exposed to sufficient heat for a sufficient period of time to finish curing the adhesive (step 312). For example, if using a BCB adhesive, the bonded layers can be cured for 40 hours in an oven at 200° C. Although a higher temperature for a shorter time period can be used to cure the BCB adhesive, the temperature can be intentionally kept lower, e.g., at 200° C., to avoid adversely affecting the piezoelectric layer included in the actuator layer 105, e.g., depoling the piezoelectric layer.

The adhesive thickness using the process 300 can have a total thickness variation (TTV) of approximately σ=10% or less (e.g. 5% or less, or 1.5% or less). By contrast, using conventional bonding techniques, the variation can be as high as 30%. That is, the thickness of the adhesive can be measured at several points and the standard deviation of the points calculated to determine the thickness variation of the adhesive across the actuator/membrane assembly. In one example, the thickness can be measured using a filmetric optical measurement device.

In other implementations, the adhesive can be applied to the both the membrane 104 and the actuator layer 105.

Referring again to the example printhead module shown in FIG. 1, in operation, fluid flows through the inlet 106 into the substrate 108 and through the inlet passage 110. Fluid flows up the ascender 114 and into the pumping chamber 112. When the actuator 102 above the pumping chamber 112 is actuated, the actuator 102 deflects the membrane 104 into the pumping chamber 112. The resulting change in volume of the pumping chamber 112 forces fluid out of the pumping chamber 112 and into the descender 116. Fluid then passes through the nozzle 118 and out of the outlet 122, provided that the actuator 102 has applied sufficient pressure to force a droplet of fluid through the nozzle 118. The droplet of fluid can then be deposited on a substrate. In one implementation, the actuator 102 is bonded to the membrane 104 after the membrane is bonded to the rest of the substrate 108.

Referring again to FIG. 2B, in the implementation shown, the piezoelectric actuator 102 includes the ground electrode 132, the piezoelectric layer 131, and the drive electrode 130. The piezoelectric layer 131 is a thin film of piezoelectric material and can have a thickness of about 50 microns or less, e.g. about 25 microns to 1 micron. In a particular example, the piezoelectric layer has a thickness in the range of approximately 8 to 18 microns.

In some implementations, the piezoelectric layer can be composed of a piezoelectric material that has desirable properties such as high density, low voids, and high piezoelectric constants. These properties can be established in a piezoelectric material by using techniques that involve firing the material prior to bonding it to a substrate. For example, piezoelectric material that is molded and fired by itself (as opposed to on a support) has the advantage that high pressure can be used to pack the material into a mold (heated or not). In addition, fewer additives, such as flow agents and binders, are typically required. Higher temperatures, 1200-1300° C. for example, can be used in the firing process, allowing better maturing and grain growth. Firing atmospheres (e.g. lead enriched atmospheres) can be used that reduce the loss of PbO (due to the high temperatures) from the ceramic. The outside surface of the molded part that may have PbO loss or other degradation can be cut off and discarded. The material can also be processed by hot isostatic pressing (HIPs), during which the ceramic is subject to high pressures, typically 1000-2000 atm. The Hipping process is typically conducted after a block of piezoelectric material has been fired, and is used to increase density, reduce voids, and increase piezoelectric constants.

Thin layers of prefired piezoelectric material can be formed by reducing the thickness of a relatively thick wafer. A precision grinding technique such as horizontal grinding and chemical mechanical polishing (CMP) can produce a highly uniform thin layer having a smooth, low void surface morphology. In horizontal grinding, a workpiece is mounted on a rotating chuck and the exposed surface of the workpiece is contacted with a horizontal grinding wheel.

The grinding and polishing can produce flatness and parallelism of, e.g., 1 micron or less, e.g. about 0.5 micron or less and surface finish to 5 run Ra or less (e.g., 1 nm) over a wafer. The grinding also produces a symmetrical surface finish and uniform residual stress. Where desired, slight concave or convex surfaces can be formed. In some implementations, the piezoelectric wafer can be bonded to a substrate, such as the module substrate, prior to grinding so that the thin layer is supported and the likelihood of fracture and warping is reduced.

In some implementations, the density of the piezoelectric material is about 7.5 g/cm³ or more, e.g., about 8 g/cm³ to 10 g/cm^{3.} The d₃₁ coefficient can be about 200 or greater. HIPS-treated piezoelectric material is available as H5C and H5D from Sumitomo Piezoelectric Materials, Japan. The H5C material exhibits an apparent density of about 8.05 g/cm³ and d₃₁ of about 210. The H5D material exhibits an apparent density of about 8.15 g/cm³ and a d₃₁ of about 300. Wafers are typically about 1 cm thick and can be diced to about 0.2 mm. The diced wafers can be bonded to the module substrate and then ground to the desired thickness. The piezoelectric material can be formed by techniques including pressing, doctor blading, green sheet, sol gel or deposition techniques. High density, high piezoelectric constant materials are preferred, but the grinding techniques can be used with lower performance material to provide thin layers and smooth, uniform surface morphology. Single crystal piezoelectric material such as lead-magnesium-niobate (PMN), available from TRS Ceramics, Philadelphia, Pa., can also be used.

The electrodes 130, 132 can be metal, such as copper, gold, tungsten, nickel-chromium (NiCr), indium-tin-oxide (ITO), titanium or platinum, or a combination of metals. The metals may be vacuum-deposited onto the piezoelectric layer 131. The thickness of the electrode layers may be, for example, about 2 micron or less, e.g. about 0.5 micron. In particular embodiments, ITO can be used to reduce shorting. The ITO material can fill small voids and passageways in the piezoelectric material and has sufficient resistance to reduce shorting. This material is advantageous for thin piezoelectric layers driven at relatively high voltages. In addition, prior to application of the electrode layers, the piezoelectric material surfaces may be treated with a dielectric to fill surface voids. The voids may be filled by depositing a dielectric layer onto the piezoelectric layer surface and then grinding or polishing the dielectric layer to expose the piezoelectric material such that any voids in the surface remain filled with dielectric. The dielectric reduces the likelihood of breakdown and enhances operational uniformity. The dielectric material may be, for example, silicon dioxide, silicon nitride, aluminum oxide or a polymer. The dielectric material may be deposited by sputtering or a vacuum deposition technique such as PECVD.

The membrane 104 is typically an inert material and has compliance so that actuation of the piezoelectric layer causes flexure of the membrane 104 sufficient to pressurize ink in the pumping chamber. The thickness uniformity of the membrane 104 provides accurate and uniform actuation across the module. The membrane material can be provided in thick plates (e.g. about 1 mm in thickness or more) which are ground to a desired thickness using horizontal grinding. For example, the membrane 104 may be ground to a thickness of about 25 microns or less, e.g. about 12 microns. In embodiments, the membrane 104 has a modulus of about 60 gigapascal or more. Example materials include glass or silicon. A particular example is a boro-silicate glass, available as Boroflot EV 520 from Schott Glass, Germany.

In the implementations discussed above, the actuator layer includes a piezoelectric layer with an electrode formed thereon, and the electrode facing surface is bonded to the membrane. In other implementations, the electrode can instead be fondled on the membrane and the adhesive can be spun-on to the piezoelectric layer to bond the piezoelectric layer to the membrane. In this implementation, the adhesive layer is formed between the lower electrode (e.g., electrode 132) and the piezoelectric layer (e.g., layer 131).

The use of terminology such as “front” and “back” and “top” and “bottom” throughout the specification and claims is for illustrative purposes only, to distinguish between various components of the printhead module and other elements described herein. The use of “front” and “back” and “top” and “bottom” does not imply a particular orientation of the printhead module. Similarly, the use of horizontal and vertical to describe elements throughout the specification is in relation to the implementation described. In other implementations, the same or similar elements can be orientated other than horizontally or vertically as the case may be.

A number of embodiments of the invention have been described. Nevertheless, it will be understood that various modifications may be made without departing from the spirit and scope of the invention. For example, the steps in the process 300 can be performed in a different order than shown and still achieve desired results. Accordingly, other embodiments are within the scope of the following claims.

What is claimed is:

1. A method for bonding a first substrate to a second substrate comprising:
coating a surface of the first substrate with an adhesive layer;
partially curing the adhesive layer to b-stage;
positioning the surface of the first substrate in contact with the second substrate;
pressing an edge of the first substrate to an edge of the second substrate to initiate Van der Waals bonding;
allowing the first and second substrates to come together by Van der Waals bonding; and
subjecting the bonded first and second substrates to a sufficient heat for a sufficient time period to cure completely the adhesive layer.

2. The method of claim 1, wherein the first substrate comprises an actuator layer including a piezoelectric layer and the second substrate comprises a silicon membrane, the method further comprising:
prior to coating the surface of the first substrate with the adhesive layer, oxygen plasma treating the surface; and
prior to positioning the first substrate and the second substrate in contact, RCA-1 cleaning the second substrate.

3. The method of claim 2, wherein the adhesive layer comprises benzocyclobutene and is spun-on to the surface of the first substrate.

4. The method of claim 1, wherein pressing an edge of the first substrate to an edge of the second substrate comprises applying a force in the range of approximately 5 to 20 psi.

5. The method of claim 1, further comprising:
prior to coating the surface of the first substrate with an adhesive layer, chemical-mechanical polishing the surface.

6. The method of claim 1, wherein:
the adhesive layer comprises benzocyclobutene; and
subjecting the bonded first and second substrates to a sufficient heat for a sufficient time period to cure completely the adhesive layer comprises heating the bonded first and second substrates to approximately 200° Celsius for approximately 40 hours.

7. The method of claim 1, wherein the adhesive layer has a total thickness variation of approximately 1.5% or less.
